(19) United States
(12) Patent Application Publication
(10) Pub. No.: US 2024/0023277 A1
(43) Pub. Date: Jan. 18, 2024

(54) HYBRID LIQUID COOLING SYSTEM WITH LEAK DETECTION

(71) Applicant: OVH, Roubaix (FR)

(72) Inventors: Alexandre Alain Jean-Pierre MENEBOO, Harnes (FR); Ali CHEHADE, Moncheaux (FR); Gregory Francis Louis BAUCHART, Wattrelos (FR)

(21) Appl. No.: 18/373,548

(22) Filed: Sep. 27, 2023

Related U.S. Application Data
(63) Continuation of application No. PCT/IB2022/052976, filed on Mar. 30, 2022.

(30) Foreign Application Priority Data
Apr. 1, 2021 (EP) 21305427.3
Aug. 31, 2021 (EP) 21306189.8

(51) Int. Cl. H05K 7/20

(52) U.S. Cl. CPC H05K 7/20272; H05K 7/20236; H05K 7/20781

(57) ABSTRACT

A hybrid cooling system that includes both immersion cooling and channelized cooling is described. The system cools an electronic device that includes a heat-generating component. The system includes a container that contains a dielectric immersion cooling liquid, the electronic device being, at least in part, immersed in the dielectric immersion cooling liquid, and a liquid cooling block through which a channelized cooling liquid is conveyed. The liquid cooling block is in thermal contact with the heat-generating component, and the channelized cooling liquid has a density that is higher than a density of the dielectric immersion cooling liquid. The system also includes a testing arrangement disposed in a bottom portion of the container, to determine the presence of the channelized cooling liquid in the bottom portion of the container, indicating a leak of the channelized cooling liquid into the dielectric immersion cooling liquid.

### CROSS-REFERENCE

The present patent application is a continuation of PCT Application PCT/IB2022/052976 filed on Mar. 30, 2022, claiming priority to European Patent Application Number 21305427.3 filed on Apr. 1, 2021, and European Patent Application Number 21306189.8, filed on Aug. 31, 2021, the contents of which are herein incorporated by reference in their entireties.

### FIELD OF TECHNOLOGY

The present technology relates to immersion-cooled electronic equipment. In particular, the present technology relates to detection of leaks of channelized fluids into the immersion fluid of an immersion-cooled electronic device.

### BACKGROUND

Electronic equipment, for example servers, memory banks, computer disks, and the like, is conventionally grouped in equipment racks. Large data centers and other large computing facilities may contain thousands of racks supporting thousands or even tens of thousands of servers.

The racks, including equipment mounted in their backplanes, consume large amounts of electric power and generate significant amounts of heat. Cooling needs are important in such racks. Some electronic devices, such as processors, generate so much heat that they could fail within seconds in case of a lack of cooling.

Fans are commonly mounted within equipment racks to provide forced ventilation cooling to rack-mounted equipment. This solution merely displaces some of the heat generated within the racks to the general environment of the data center, and also takes up significant space on the racks, e.g., reducing the number of servers per square meter of data center space.

Liquid cooling, in particular water cooling, has been used as an addition or replacement to traditional forced-air cooling. Cold plates, for example water blocks having internal channels for water circulation, may be mounted on heat-generating components, such as processors, to displace heat from the processors toward heat exchangers. Air-to-liquid heat exchangers, for example finned tube heat exchangers similar to radiators, may be mounted to the racks to absorb and transport some of this displaced heat toward external cooling equipment, for example cooling towers, located outside of the data center.

Immersion cooling (sometimes called immersive cooling) was more recently introduced. Electronic components are inserted in a container that is fully or partially filled with a non-conducting cooling liquid, for example an oil-based dielectric cooling liquid. Good thermal contact is obtained between the electronic components and the dielectric cooling liquid. However, an electronic component, for example a server, includes some devices, such as processors, which may generate most of the heat while other devices, such as memory boards, may generate much less heat. It is generally necessary to ensure circulation of the dielectric cooling liquid within the container, at a level that is sufficient to cool the hottest devices within the electronic components. This requires the use of efficient pumps that consume a significant amount of energy. Heat sinks may be mounted on some heat-generating devices. Some other heat-generating devices may have porous surfaces so that the contact between these devices and the dielectric cooling liquid is more intimate and thus more thermally efficient. These solutions only provide a modest reduction of the amount of energy required to operate the pumps that circulate the dielectric cooling liquid within the container.

Immersion cooling systems also commonly take the form of large tanks in which the electronic devices are submerged. These tanks and the liquid circulation and heat exchange systems that are conventionally used with them typically require a significant amount of space, and in many instances are not intended to be mounted in racks. While there are some immersion-cooled devices that can be mounted in racks, this typically requires that the cases surrounding the electronic devices and immersion cooling liquid in which they are submerged be sealed, to prevent spillage of the cooling liquids, and for use in “two-phase” immersion systems in which the immersion cooling liquid may boil within the case. Such sealed systems may be expensive to manufacture, and may involve pumping systems to fill and drain the cases.

Hybrid systems, in which an electronic device having some components cooled via water blocks is also cooled via immersion cooling have also been used. The liquid used in the water blocks, e.g. water, may be different than the dielectric cooling liquid in which the electronic device is immersed, and may cause damage if it leaks into the dielectric cooling liquid.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on developers' appreciation of shortcomings associated with the prior art. In particular, such shortcomings may include the difficulty of detecting leaks of a channelized liquid, such as is used in water blocks, into the dielectric cooling liquid in a cooling system that uses both water blocks (or other liquid-cooled cold plates), and by immersion cooling.

In accordance with one aspect of the present disclosure, the technology is implemented as a hybrid cooling system that cools an electronic device that includes a heat-generating component. The system includes a container that contains a dielectric immersion cooling liquid, the electronic device being, at least in part, immersed in the dielectric immersion cooling liquid, and a liquid cooling block through which a channelized cooling liquid is conveyed. The liquid cooling block is in thermal contact with the heat-generating component, and the channelized cooling liquid has a density that is higher than a density of the dielectric immersion cooling liquid. The system also includes a testing arrangement disposed in a bottom portion of the container, to determine the presence of the channelized cooling liquid in the bottom portion of the container, indicating a leak of the channelized cooling liquid into the dielectric immersion cooling liquid.

In some embodiments, the container includes an immersion case containing the electronic device. In some embodiments, the dielectric immersion liquid flows over the electronic device, and the container includes a collection tray disposed below the electronic device that collects liquid flowing off of the electronic device.

In some embodiments, the testing arrangement includes a float arrangement including a floating element and a detector that determines when the floating element has reached a predetermined height above a bottom of the container, indicating a leak. The floating element has a density that is higher than the density of the dielectric immersion cooling liquid and lower than a density of the channelized cooling liquid, such that the floating element is configured to sink in the dielectric immersion cooling liquid and to float on top of the channelized cooling liquid. In some embodiments, the float arrangement further includes a constraining mechanism that constrains the motion of the floating element.

In some embodiments, the channelized cooling liquid has a greater conductivity than the dielectric immersion cooling liquid, and the testing arrangement includes a conductivity sensor. In some embodiments, the channelized cooling liquid has a pH that is different from a pH of the dielectric immersion cooling liquid, and the testing arrangement includes a pH sensor.

In some embodiments, the testing arrangement includes a resealable closure configured to provide access to a sample of liquid from the bottom portion of the container. In some embodiments, the resealable closure includes a valve.

In some embodiments, the testing arrangement is mounted in the container through a standardized opening in the bottom portion of the container. The standardized opening is configured to receive any one of a variety of testing arrangements.

In some embodiments, the channelized cooling liquid is conductive and the testing arrangement includes circuitry including a first conducting strip and a second conducting strip that are separated by a non-conducting region of the circuitry. A circuit formed by the first conducting strip and the second conducting strip is closed when at least a portion of the first conducting strip and at least a portion of the second conducting strip are submerged in the channelized cooling liquid. In some embodiments, the circuitry includes flexible circuitry attached to a surface of the bottom portion of the container using an adhesive. In some embodiments, the circuitry includes a printed circuit board.

In some embodiments, a bottom surface of the container is sloped.

In some embodiments, the hybrid cooling system further includes an alarm system that is activated to inform an operator when a leak of the channelized cooling liquid into the dielectric immersion cooling liquid is detected.

In accordance with another aspect of the present disclosure, the technology is implemented as a hybrid cooling system that cools an electronic device including a heat-generating component. The hybrid cooling system comprises a container, a liquid cooling block and a testing arrangement. The container is adapted and configured to receive a dielectric immersion cooling liquid so that the electronic device is, at least in part, immersed in the dielectric immersion cooling liquid when the dielectric immersion liquid is present in the container. The liquid cooling block is adapted and configured to circulate a channelized cooling liquid, the liquid cooling block in thermal contact with the heat-generating component, the channelized cooling liquid having a density that is higher than a density of the dielectric immersion cooling liquid. The testing arrangement is disposed in a bottom portion of the container, to determine a presence of the channelized cooling liquid in the bottom portion of the container, indicating a leak of the channelized cooling liquid into the dielectric immersion cooling liquid.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

In the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

These and other features, aspects and advantages of the present technology will become better understood with regard to the following description, appended claims and accompanying drawings where:

FIG. 1 shows a perspective view of a rack system for housing numerous rack-mounted assemblies.

FIG. 2 shows another perspective view of the rack system.

FIG. 3 shows a perspective view of a rack-mounted assembly.

FIG. 4 shows a conceptual block diagram of a rack-mountable, non-sealed hybrid liquid cooling system.

FIG. 5 shows a vertically oriented flow-through non-sealed immersion cooling rack system.

FIG. 6 shows a cut-away view of one of the rack-mounted assemblies that may be mounted in the rack system of FIG. 5.

FIG. 7 shows the bottom portion of an immersion case including a testing arrangement that includes a float arrangement, in accordance with various embodiments of the disclosure.

FIG. 8 shows the bottom portion of an immersion case including a testing arrangement that includes a conductivity sensor, in accordance with various embodiments of the disclosure.

FIG. 9 shows the bottom portion of an immersion case including a testing arrangement that includes a pH sensor, in accordance with various embodiments of the disclosure.

FIG. 10 shows the bottom portion of an immersion case including a testing arrangement that includes a valve, in accordance with various embodiments of the disclosure.

FIG. 11 shows the bottom portion of an immersion case including a testing arrangement that includes circuitry having at least two conductive strips, in accordance with various embodiments of the disclosure.

It should also be noted that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative systems embodying the principles of the present technology.

With these fundamentals in place, we will now consider some non-limiting examples to illustrate various implementations of aspects of the present disclosure.

### Immersion Cooling Rack System

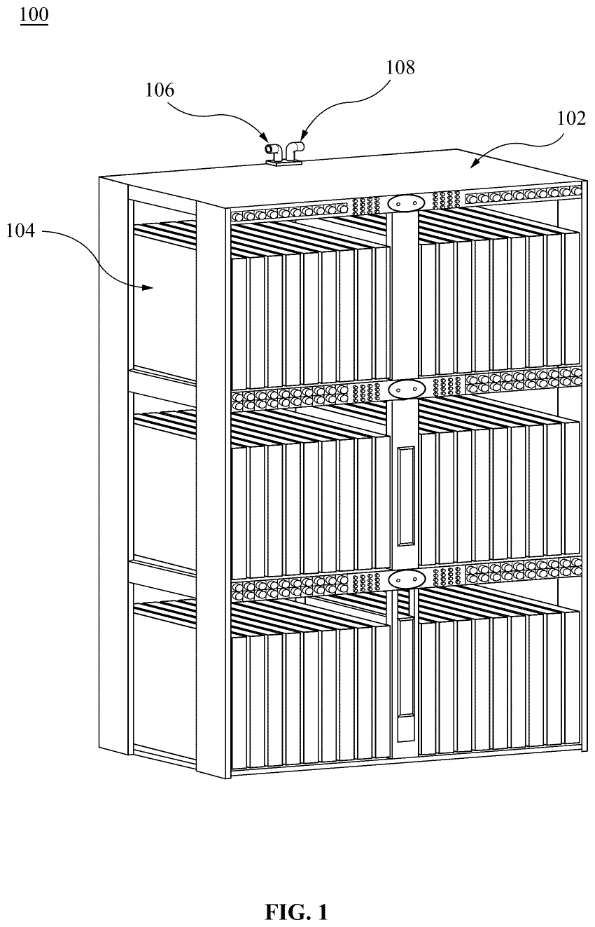

FIG. 1 shows a perspective view of a rack system 100 for housing numerous rack-mounted assemblies 104. As shown, the rack system 100 may include a rack frame 102, rack-mounted assemblies 104, a liquid cooling inlet conduit 106 and a liquid cooling outlet conduit 108. As described more fully below, the rack-mounted assemblies 104 may be oriented vertically with respect to the rack frame 102, resembling books on a library shelf. This arrangement may provide for mounting a large number of such rack-mounted assemblies 104 in the rack frame 102, relative to conventional arrangements, particularly with respect to conventional arrangements of immersion-cooled rack-mounted assemblies.

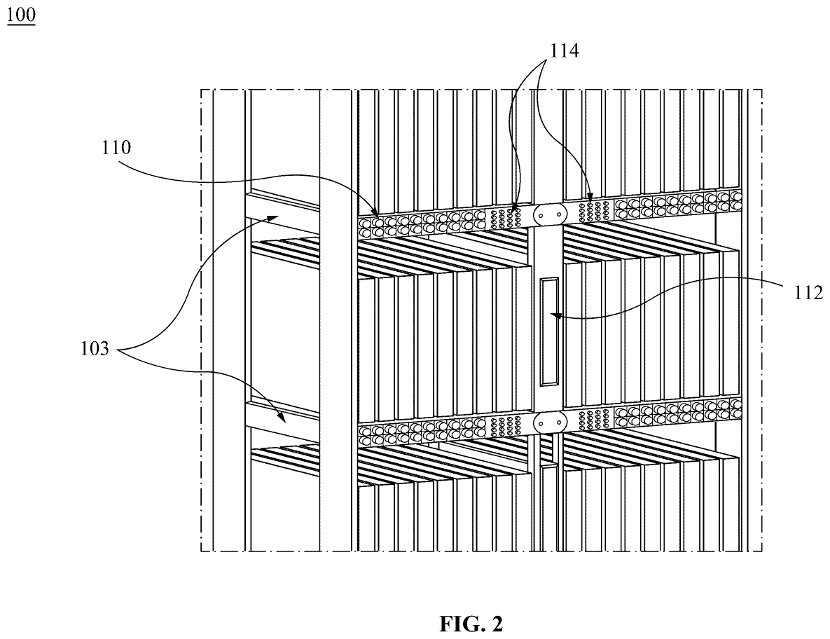

FIG. 2 shows another perspective view of the rack system 100. As shown, the rack system 100 may further comprise a power distribution unit 110, a switch 112, and liquid coolant inlet/outlet connectors 114. It is to be noted that the rack system 100 may include other components such as heat exchangers, cables, pumps or the like, however, such components have been omitted from FIGS. 1 and 2 for clarity of understanding. As shown in FIGS. 1 and 2, the rack frame 102 may include shelves 103 to accommodate one or more rack-mounted assemblies 104. As noted above, the one or more rack-mounted assemblies 104 may be arranged vertically with respect to the shelves 103. In some embodiments, guide members (not shown) may be used on the shelves 103 to guide the rack-mounted assemblies 104 into position during racking and de-racking, and to provide proper spacing between the rack-mounted assemblies 104 for racking and de-racking.

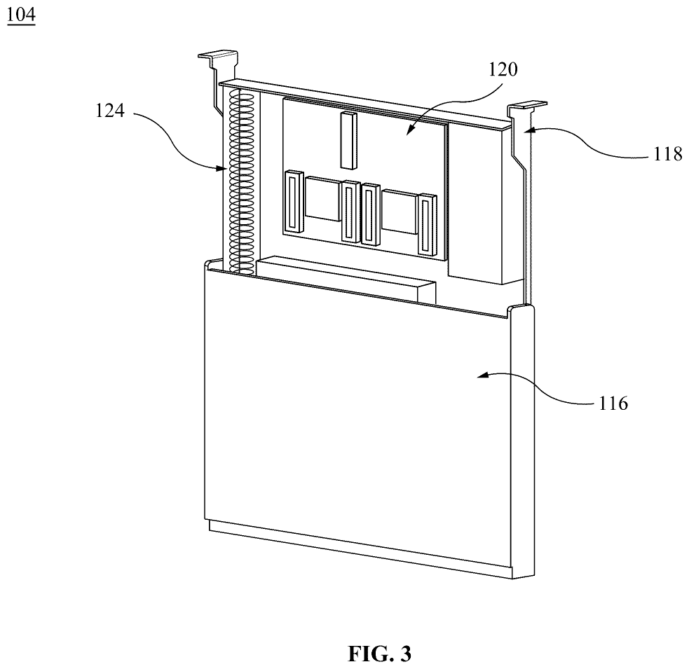

FIG. 3 shows a perspective view of a rack-mounted assembly 104. As shown, the rack-mounted assembly 104 may include an immersion case 116 and a detachable frame 118. The detachable frame 118 may hold an electronic device 120 and may be immersed in the immersion case 116. Although the immersion case 116, detachable frame 118, and electronic device 120 are show as separate parts, it will be understood by one of ordinary skill in the art that, in some embodiments, two or more of these components could be combined. For example, components of the electronic device 120 could be fixed directly on the detachable frame 118 and/or the immersion case 116.

It is contemplated that the electronic device 120 may generate a significant amount of heat. Consequently, the rack system 100 may use a cooling system to cool down the electronic device 120 to prevent the electronic device 120 from being damaged. The cooling system may be an immersion cooling system. As used herein, an immersion cooling system is a cooling system in which the electronic device is in direct contact with a non-conductive (dielectric) cooling liquid, which either flows over at least portions of the electronic device, or in which at least portions of the electronic device are submerged. For example, in the rack-mounted assembly 104, the immersion case 116 may contain a dielectric immersion cooling liquid (not shown in FIG. 3). Further, the detachable frame 118 including the electronic device 120 may be submerged in the immersion cooling case 116. In some embodiments, the dielectric immersion cooling liquid and the detachable frame 118 may be inserted into the immersion case 116 via an opening 122 at the top of the immersion case 116. In some embodiments, the opening 122 may remain at least partially open during operation of the electronic device 120, providing a non-sealed configuration for the immersion case 116. Such non-sealed configurations may be easier to manufacture and maintain than sealed configurations, but may be inappropriate for, e.g., two-phase systems, in which the immersion cooling liquid may boil during operation of the electronic device 120.

In some embodiments, the immersion case 116 may also include structures or devices for cooling the dielectric cooling liquid. For example, a convection-inducing structure, such as a serpentine convection coil 124 may be used to cool the dielectric cooling liquid via natural convection. Alternatively or additionally, a pump (not shown) may be used to circulate the dielectric cooling liquid either within the immersion case 116 or through an external cooling system (not shown). In some embodiments, a two-phase system in which dielectric cooling liquid in a gaseous phase is cooled by condensation may be used. Generally, any technology or combination for cooling the dielectric cooling liquid may be used without departing from the principles disclosed herein.

The electronic device 120 may be connected to the power distribution unit 110 and the switch 112 via power and network cables (not shown) to facilitate powering the electronic device 120 and to facilitate communication between the electronic device 120 and external devices (not shown) through the switch 112.

In some embodiments, in addition to immersion cooling, certain heat-generating components of the electronic device 120 may be cooled using one or more thermal transfer devices, which may also be called “cold plates” or “water blocks” (although a liquid circulating through the “water blocks” may be any of a wide variety of known thermal transfer liquids, rather than water). Examples of heat-generating components that may be cooled using such a thermal transfer devices include, but are not limited to, central processing units (CPUs), graphics processing units (GPUs), neural processing units (NPUs), tensor processing units (TPUs), power supply circuitry, and application specific integrated circuits (ASICs), including, for example, ASICs configured for high-speed cryptocurrency mining.

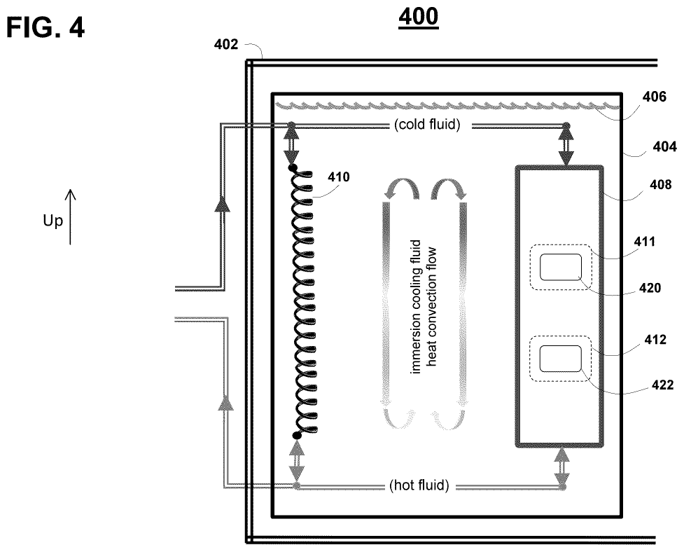

FIG. 4 shows a conceptual block diagram of such an embodiment, which may be referred to as a “hybrid” liquid cooling system, since it includes both immersion cooling and a liquid cooling system that circulates a liquid coolant through a loop that includes thermal transfer devices, such as “water blocks” on some heat-generating components of the electronic device. As illustrated in FIG. 4, a hybrid liquid cooling system 400 is housed within an immersion case 404, which is part of a rack-mounted assembly (not shown in full in FIG. 4) that is mounted in a rack frame 402, such as is described above with reference to FIGS. 1 and 2. The immersion case 404 contains a volume of dielectric immersion cooling liquid 406 and at least one electronic device 408 that is submerged in the dielectric immersion cooling liquid 406.

The immersion case 404 may also contain a serpentine convection coil 410 that is also submerged within the dielectric immersion cooling liquid 406. The serpentine convection coil 410 is structured with multiple hollow-channel coils to provide a high surface area exposure relative to the dielectric immersion liquid 406 while also maintaining compact overall length and width dimensions. With this structure, the serpentine convection coil 410 is configured to cool the ambient temperature and induce natural thermal convection in the the dielectric immersion cooling liquid 406 through direct channelized liquid cooling. That is, the serpentine convection coil 410 internally conveys a circulating channelized cooling liquid that operates to cool the dielectric immersion cooling liquid 406. The channelized cooling liquid may be a different liquid than the dielectric immersion cooling liquid 406. That is, the channelized cooling liquid may include water, alcohol, or any suitable liquid capable of sustaining adequate cooling temperatures. It will be understood that although the system shown in FIG. 4 uses the serpentine convection coil 410 for cooling the dielectric immersion cooling liquid 406, other convection-inducing structures (not shown) or other cooling technologies (not shown), as discussed above, could be used instead of or in addition to the serpentine convection coil 410.

As noted above, the electronic device 408 includes heat-generating components 411 and 412 that are also submerged within the dielectric immersion cooling liquid 406. To provide further cooling to the heat-generating components 411, 412, and as a supplement to the overall immersion cooling of the electronic device, channelized liquid cooling may be used. Cooling blocks 420, 422 may be arranged to be in direct thermal contact with the one or more heat-generating components 411, 412. The cooling blocks 420, 422 are structured to convey the circulating channelized cooling liquid to provide additional cooling to the heat-generating components 411, 412.

The channelized liquid cooling of the hybrid liquid cooling system 400 forms a fluid distribution loop. The fluid distribution loop circulates the channelized cooling liquid through the cooling blocks 420, 422 to cool the heat-generating components 411, 412, and through the serpentine convection coil 410, to cool and induce convection in the dielectric immersion cooling liquid 406. After absorbing heat from the heat-generating components 411, 412 and from the dielectric immersion cooling liquid 406, the heated channelized cooling liquid is conveyed through a heat exchange system (not shown), the operation of which will generally be familiar to those of skill in the art. The heat exchange system cools the channelized cooling fluid, after which it may be recirculated through the fluid distribution loop.

It will be understood that there may be many additional features, combinations, and variations of such hybrid systems. For example, in some embodiments, the immersion case may be open (as shown), while in other embodiments, the immersion case may be sealed. In some embodiments, multiple electronic devices, similar to the electronic device 408, may be immersed in a single immersion case or immersion tank.

In some embodiments, the immersion case may include an overflow release (not shown), such as an opening or tube near the top of the immersion case, that is configured to permit immersion liquid to flow into an overflow collection channel connected to the rack system in the event of an overflow of the immersion liquid. Because some of the dielectric liquids that are used as immersion liquids may be expensive, such an overflow release may prevent these liquids from being lost in the event of an overflow.

Other variations may involve changing the order of the components and/or the serpentine convection coil in the fluid distribution loop. For example, the channelized cooling fluid may flow through the serpentine convection coil before flowing through the cooling blocks. In some embodiments, the serpentine convection coil may be part of a different fluid distribution loop than the cooling blocks. In some variations, the serpentine convection coil may be entirely absent, or may be replaced with other convection-inducing structures or devices for circulating the dielectric immersion cooling liquid. These variations and additional features may be used in various combinations, and may be used in connection with the embodiments described above, or other embodiments.

### Flow-Through Immersion Cooling System

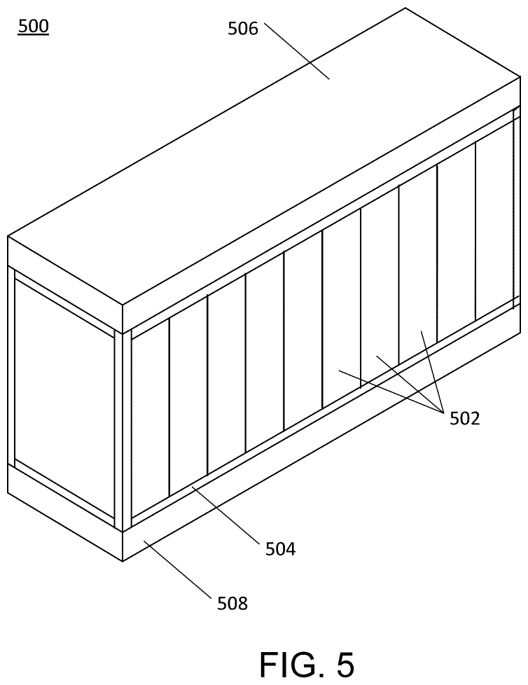

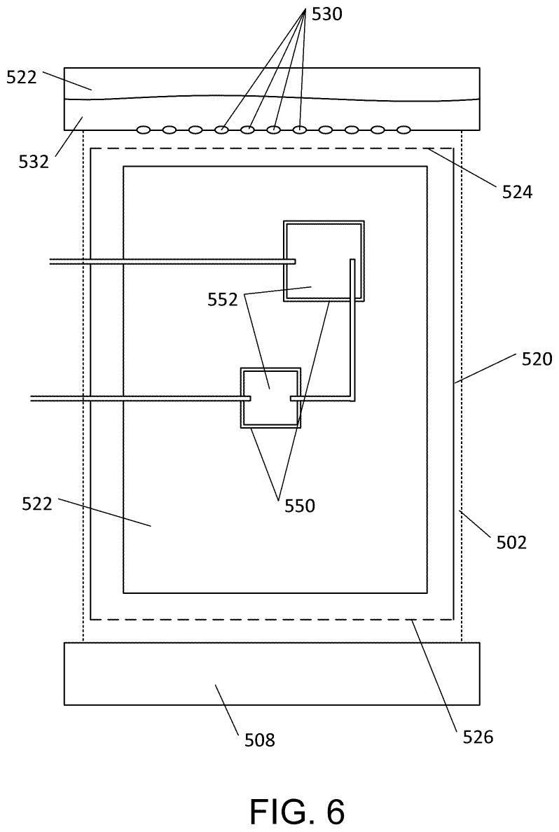

In another type of immersion cooling system, such as is shown in FIGS. 5 and 6, the immersion cooling liquid flows over the electronic devices due to gravity. FIG. 5 shows such a rack system 500, in which numerous rack-mounted assemblies 502 are mounted vertically within a rack frame 504. A channel 506 for an immersion cooling liquid (not shown in FIG. 5) is mounted in the rack frame 504 above the rack-mounted assemblies 502, and a collection tray 508 for receiving immersion cooling liquid is mounted in the rack frame 504 below the rack-mounted assemblies 502. It will be understood that the channel 506 and collection tray 508 may be most any kind of receptacles capable of holding fluid, such as tanks, containers, and the like.

As seen in FIG. 6, which shows a cut-away view of one of the rack-mounted assemblies 502 of the rack system 500, the rack-mounted assembly 502 includes an immersion case 520, in which an electronic device 522 is disposed. A top portion 524 of the immersion case 520 is open, as is a bottom portion 526 of the immersion case 520. The channel 506 includes openings 530, through which the immersion cooling liquid 532 pours onto the electronic device 522. The immersion cooling liquid 532 flows over the electronic device 522, and into the collection tray 508. As the immersion cooling liquid 532 flows over the electronic device 522, it absorbs heat from various heat-generating components of the electronic device 522 and conveys the heat away from those components. Heated immersion cooling liquid 532 is removed from the collection tray 508, e.g. by pumping or by gravity, and is pumped through a heat exchange system (not shown), the operation of which will generally be familiar to those of skill in the art. The heat exchange system cools the immersion cooling liquid 532, after which it is pumped back into a channel, such as the channel 506 of the system 500.

In addition to immersion cooling, certain heat-generating components 550 of the electronic device 522 may be cooled using one or more thermal transfer devices 552, which may also be called “cold plates” or “water blocks” (although a liquid circulating through the “water blocks” may be any of a wide variety of known thermal transfer liquids, rather than water). Examples of heat-generating components 550 that may be cooled using the thermal transfer devices 552 include, but are not limited to, central processing units (CPUs), graphics processing units (GPUs), neural processing units (NPUs), tensor processing units (TPUs), power supply circuitry, and application specific integrated circuits (ASICs), including, for example, ASICs configured for high-speed cryptocurrency mining.

It will be understood that there are many possible variations of the system 500 as described with reference to FIGS. 5 and 6. For example, in some embodiments, the channel 506 and/or the collection tray 508 may be parts of a rack-mounted assembly 502, so when the rack-mounted assembly 502 is de-racked, the channel 506 and/or collection tray 508 associated with that rack-mounted assembly 502 are also removed. In other embodiments, the channel 506 and/or collection tray 508 may be attached to the rack frame 504, such that when the rack-mounted assembly 502 is de-racked, the channel 506 and/or collection tray 508 remain attached to the rack frame 504.

Additionally, the channel 506 and collection tray 508 may be associated with a single rack-mounted assembly 502, or with more than one rack-mounted assembly 502. For example, in some embodiments, the channel 506 may cover the entire width of the rack frame 504, with openings providing immersion cooling liquid to an entire row of rack-mounted assemblies 502. Similarly, the collection tray 508 may collect immersion cooling liquid from, e.g., an entire row of rack-mounted assemblies 502.

It will similarly be understood that in some embodiments, the immersion cooling liquid 532 may flow over the electronic devices associated with more than one rack-mounted assembly 502 before pouring into the collection tray 508. For example, the rack-mounted assemblies may be arranged so that the opening in the bottom portion of the non-sealed immersion case of a first rack-mounted assembly is arranged above the opening in the top portion of the non-sealed immersion case of a second rack-mounted assembly, so that when the immersion cooling liquid pours out of the bottom of the first rack-mounted assembly, it pours into the top of the second rack-mounted assembly, to cool the electronic device associated with the second rack-mounted assembly. In this manner, a single stream of immersion cooling liquid may be used to cool numerous vertically aligned rack-mounted assemblies.

Additionally, in some embodiments, the openings 530 may include nozzles (not shown), which may be adjustable to control the flow of the immersion cooling liquid 532 from the channel 506. Such nozzles may also be configured to spray or mist the immersion cooling liquid 532 onto the electronic device rather than pouring or dripping the immersion cooling liquid 532 onto the electronic device. Pressure to accommodate such spraying of the immersion cooling liquid 532 onto the electronic device may be arranged, for example, by filling the channel 506 to increase the hydrostatic pressure or by pumping the immersion cooling liquid 532 through the channel 506 to provide hydraulic pressure.

In some embodiments, the rack-mounted assemblies may be mounted at a non-vertical angle. Alternatively or additionally, the electronic devices within the rack-mounted assemblies may be mounted at a non-vertical angle within the ranck-mounted assemblied. In general, such non-vertical mounting may decrease the flow speed of the immersion cooling liquid over the electronic devices.

### Leak Detection

As has been discussed above, cooling systems for electronic devices may include both immersion cooling systems, in which the electronic devices are immersed or submerged in a dielectric immersion cooling liquid and “channelized” cooling systems, in which heat transfer devices such as water blocks are used to cool components of the electronic device, using a liquid that flows through channels between and within the heat transfer devices.

In some cases, the same liquid may be used as both the dielectric immersion cooling liquid and the channelized cooling liquid (i.e., the liquid that flows through the water blocks). However, in some systems, the characteristics of the dielectric immersion cooling liquid and/or the cost of the dielectric immersion cooling liquid may render it inappropriate for use in the channelized cooling system. Often, the channelized cooling liquid will be water, or some other liquid that provides appropriate heat transfer characteristics for the channelized cooling system, but may not be usable for immersion cooling, e.g., due to its conductivity or due to damage that it may cause to components of the electronic device. For example, if water is used as the channelized cooling liquid, it is likely that the concentration of ions in the water will cause the water to be conductive enough to cause damage to electronic components. Even if the water starts as distilled or deionized water, the concentration of ions will increase as the water is circulated through the cooling system.

To avoid damage to immersed or submerged electronic devices, it is desirable to determine whether channelized cooling liquid is leaking into the dielectric immersion cooling liquid. Dielectric immersion cooling liquids are typically either hydrocarbon- or fluorocarbon-based and typically have densities that are lower than the density of water. If the channelized cooling liquid has a higher density than the dielectric immersion cooling liquid, which will typically be the case, then if the channelized cooling fluid leaks into the immersion cooling liquid, it will sink to a bottom portion of the immersion case or collection tray (in the case of flow-through systems).

In accordance with various embodiments of the disclosure, a testing arrangement, such as a sensor, may be used in a bottom portion of the immersion case or collection tray to detect the presence of the channelized cooling liquid, which would indicate that there is a leak in the channelized cooling system. Generally, this bottom portion of the immersion case should be far enough below any immersed or submerged electronic device that, absent a major leak, the channelized cooling fluid will not collect around any components of the electronic device. Once the fluid is detected, an alarm may be raised, or an operator may otherwise be informed of the unit in which the leak was detected so that remedial measures may be taken.

It should be noted that, although the embodiments disclosed below are described as having testing arrangements in a bottom portion of an immersion case, in flow-through systems, the same testing arrangements may be used, mutatus mutandis, in a bottom portion of a collection tray. Additionally, although the embodiments disclosed below each shows a single testing arrangement, disposed at a particular location in the bottom portion of an immersion case, it will be understood that combinations of such testing arrangements may be used, and that the precise placement of the testing arrangements may vary.

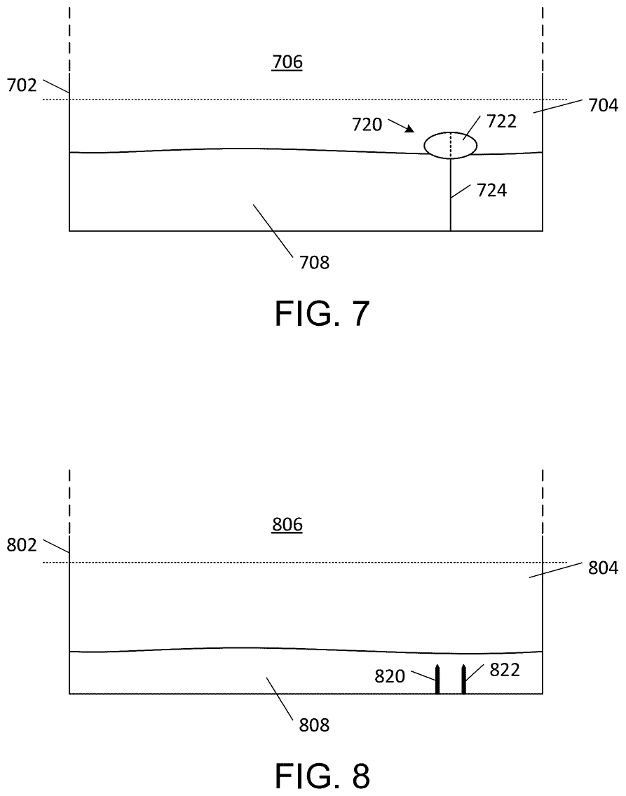

FIG. 7 shows a bottom portion 704 of an immersion case 702 of a hybrid cooling system that includes both immersion cooling and channelized cooling. The immersion case 702 contains a dielectric immersion cooling liquid 706. In the example shown in FIG. 7, a leak has occurred in the channelized cooling system, so channelized cooling liquid 708 has collected at the bottom of the immersion case 702. To detect the presence of this liquid, the embodiment shown in FIG. 7 uses a float arrangement 720. The float arrangement 720 includes a floating element 722, and a rod 724, which constrains the motion of the floating element 722 and includes, e.g. a switch (not shown) or other mechanism that detects when the floating element 722 rises to a predetermined height along the rod 724.

The floating element 722 has a density that is higher than the density of the dielectric immersion cooling liquid but lower than the density of the channelized cooling liquid. This means that the floating element 722 will sink in the dielectric immersion cooling liquid and float on top of the channelized cooling liquid. Thus, if no leak has occurred, the floating element 722 will rest at the bottom of the immersion case 702 (and at the bottom of the rod 724). As increasing amounts of the channelized cooling liquid leak and sink to the bottom of the immersion case 702, the floating element 722 will rise to float on top of the channelized cooling liquid. This motion along the rod 724 may be detected using a switch or other detector to determine when the floating element 722 has reached a predetermined height above the bottom of the immersion case. Such detectors will generally be familiar to those of skill in the art.

It will be understood that there may be many changes or variations that may be used. While FIG. 7 shows one type of float arrangement 720, it will be recognized by those having ordinary skill in the art that a wide variety of float arrangements having a floating element or material that floats on top of the channelized cooling liquid could be used. Additionally, the rod 724 may be replaced by another constraining mechanism that constrains the motion of the floating element 722, such as a cage (not shown) or a tether (not shown). Further, in some embodiments, the float arrangement may be structured as a single unit that may be mounted within the immersion case through a “standardized” opening in the bottom portion of the immersion case, which is configured to receive any of a variety of sensors or other testing arrangements for determining the presence of the channelized cooling liquid in the bottom portion of the immersion case.

FIG. 8 shows an embodiment, in which the varying electrical properties of the liquids are used to detect a leak. A bottom portion 804 of an immersion case 802 of a hybrid cooling system that includes both immersion cooling and channelized cooling is shown. The immersion case 802 contains a dielectric immersion cooling liquid 806. The bottom portion 804 of the immersion case 802 also includes electrodes 820 and 822, which are used to measure the conductivity of the liquid between the electrodes 820 and 822. This may be done, e.g., by imposing a constant voltage between the electrodes 820 and 822, and measuring changes in the current that occur as a result of the conductivity/resistivity of the liquid. It will be understood that other known methods for measuring conductivity/resistivity could also be used.

The dielectric immersion cooling liquid 806 has very low conductivity. Thus, when there has been no leak, there will be low conductivity (or high resistivity) between the electrodes 820 and 822. In the example shown in FIG. 8, a leak has occurred in the channelized cooling system, so channelized cooling liquid 808 has collected at the bottom of the immersion case 802. The conductivity of the channelized cooling liquid 808 is much higher than the conductivity of the dielectric immersion cooling liquid 806. This difference in conductivity is detected by the electrodes 820 and 822, indicating that a leak has occurred.

It will be understood by those of ordinary skill in the art that many variations on a system that uses conductivity or resistivity measurement to detect the presence of the channelized cooling liquid may be used. For example, the electrodes may be disposed within a single unit or holder that is open to liquid, and that holds the electrodes at a predetermined distance from each other. In some embodiments, such a holder may be configured to be mounted in the immersion case through a “standardized” opening in the bottom portion of the immersion case, which is configured to receive any of a variety of sensors or other testing arrangements for determining the presence of the channelized cooling liquid in the bottom portion of the immersion case.

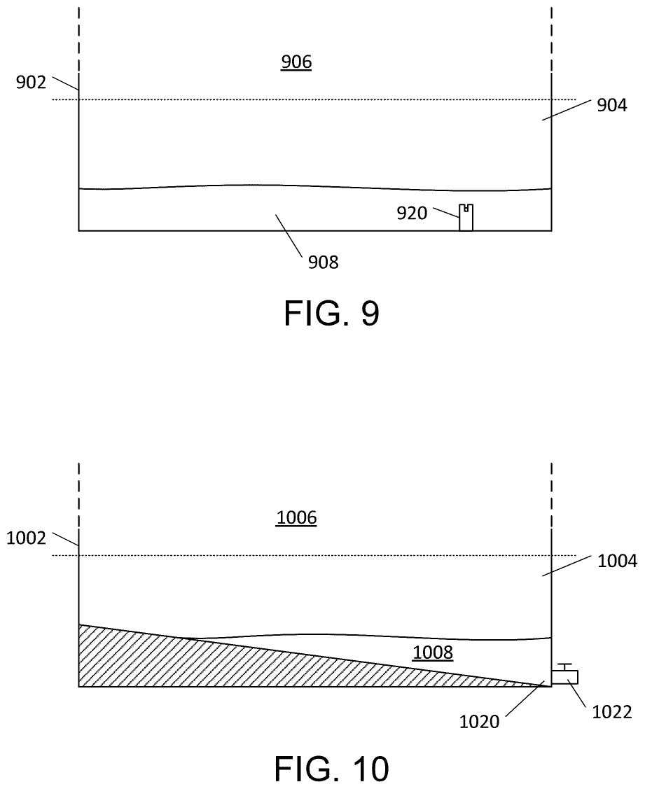

FIG. 9 shows an embodiment in which a difference in pH is used to detect a leak. A bottom portion 904 of an immersion case 902 of a hybrid cooling system that includes both immersion cooling and channelized cooling is shown. The immersion case 902 contains a dielectric immersion cooling liquid 906. The bottom portion 904 of the immersion case 902 also includes a pH sensor 920, which are used to measure the pH of the liquid in the immediate vicinity of the pH sensor 920. It will be understood that any known electrical, electrochemical, or electronic method for measuring pH could be used by the pH sensor 920.

The dielectric immersion cooling liquid 906 and the channelized cooling liquid may have different pH values. The liquids may be selected to have this characteristic, or the pH may be measurably different simply due to chemical differences between the two liquids. In the example shown in FIG. 9, a leak has occurred in the channelized cooling system, so channelized cooling liquid 908 has collected at the bottom of the immersion case 902. The pH sensor 920 will detect that the liquid in the immediate vicinity of the pH sensor has a different pH than the dielectric immersion cooling liquid 906, indicating that a leak has occurred.

As with other embodiments, it will be understood by those of ordinary skill in the art that many variations on a system that uses pH measurements to detect the presence of the channelized cooling liquid may be used. For example, the pH sensor may be configured to be mounted in the immersion case through a “standardized” opening in the bottom portion of the immersion case, which is configured to receive any of a variety of sensors or other testing arrangements for determining the presence of the channelized cooling liquid in the bottom portion of the immersion case.

Referring now to FIG. 10, a further embodiment of a testing arrangement for detecting leaks is described. A bottom portion 1004 of an immersion case 1002 of a hybrid cooling system that includes both immersion cooling and channelized cooling is shown. The immersion case 1002 contains a dielectric immersion cooling liquid 1006. The bottom portion 1004 of the immersion case 1002 is sloped, to cause any channelized cooling liquid that leaks into the bottom portion 1004 to collect at a lower end 1020 of the bottom portion 1004. It will be understood that such a sloped bottom portion may be used with any of the embodiments described herein.

The bottom portion 1004 of the immersion case 1002 includes a valve 1022 disposed in a front wall 1024 of the bottom portion 1004. As shown in FIG. 10, a leak has occurred, so channelized cooling liquid has collected at the lower end 1020 of the bottom portion 1004. The valve 1022 permits an operator to sample liquid from the bottom portion 1004, which may be manually tested to determine whether channelized cooling liquid 1008 is present, indicating that a leak has occurred. The valve 1022 may also be used to drain leaked channelized cooling liquid from the bottom portion 1004.

It will be understood that most any type of valve or resealable closure, including, e.g., a needle-penetrable resealable closure, may be used in various embodiments. Many such variations of the embodiment shown in FIG. 10 may be used. For example, the bottom portion 1004 being sloped is optional. Additionally, although the valve 1022 is shown as being disposed in a front wall 1024 of the bottom portion 1004, this placement is primarily for convenience of operator access, and such a valve could be disposed in other locations. For example, the valve 1022 may be placed on a bottom wall of the bottom portion 1004, as is the case with the sensors in the embodiments discussed above. It should also be noted that the sensors in the embodiments discussed above may be disposed in a front wall of the bottom portion or at other locations in the bottom portion of the immersion case. Additionally, as with other embodiments, the valve may be configured to be mounted in the immersion case through a “standardized” opening in the bottom portion of the immersion case, which is configured to receive any of a variety of sensors or other testing arrangements for determining the presence of the channelized cooling liquid in the bottom portion of the immersion case.

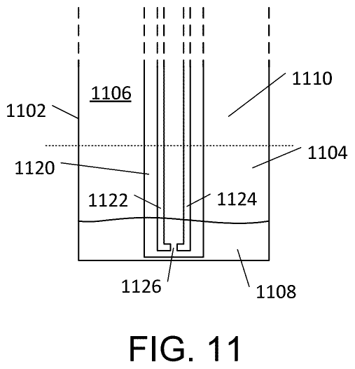

Referring to FIG. 11, another embodiment is described. In the embodiment of FIG. 11, a bottom portion 1104 of an immersion case 1102 of a hybrid cooling system that includes both immersion cooling and channelized cooling is shown in a view that includes a rear wall 1110. The immersion case 1102 contains a dielectric immersion cooling liquid 1106. Circuitry 1120, is attached to the rear wall 1110, and includes two conducting strips 1122 and 1124 that are separated by a non-conducting region 1126. At least a portion of the conducting strips 1122 and 1124, such as the bottom portion, is exposed to the liquid in the bottom portion 1104. The circuitry 1120 may be, e.g., flexible circuitry attached to the rear wall 1110 using an adhesive. Alternatively, the circuitry 1120 may be a rigid printed circuit board, or any other form of circuitry that may be attached to the rear wall 1110.

When exposed portions of the conducting strips 1122 and 1124 are submerged in the dielectric immersion cooling liquid 1106, a circuit formed by the conducting strips 1122 and 1124 is open, since the dielectric immersion cooling liquid 1106 is non-conductive. FIG. 11 shows an instance in which a channelized cooling liquid 1108 has leaked. When exposed portions of the conducting strips 1122 and 1124 are submerged, at least in part, in the channelized cooling liquid 1108, the circuit formed by the conducting strips 1122 and 1124 is closed, since the channelized cooling liquid conducts electricity between the conducting strips 1122 and 1124. If the circuit formed by the conducting strips 1122 and 1124 is closed, then a leak has been detected.

It will be understood that many variations of the testing arrangement shown in FIG. 11 may be used. For example, additional pairs of conducting strips (not shown) may be added to the circuitry 1120, either for redundancy, or with exposed portions at various heights, to detect a height of the channelized cooling liquid. Additionally, although the circuitry 1120 is shown on the rear wall 1110, a similar strip may be attached to other walls of the bottom portion 1104, including, e.g., any side walls or a bottom wall or surface.

It will be understood that, although the embodiments presented herein have been described with reference to specific features and structures, various modifications and combinations may be made without departing from the disclosure. For example, it is contemplated that in some embodiments, two or more of the testing arrangements described above may be used, in any combination. For instance, an embodiment may use a combination of a pH sensor and a conductivity sensor to detect leaks, and may also include a valve to permit manual testing and draining of leaked channelized cooling liquid. The specification and drawings are, accordingly, to be regarded simply as an illustration of the discussed implementations or embodiments and their principles as defined by the appended claims, and are contemplated to cover any and all modifications, variations, combinations or equivalents that fall within the scope of the present disclosure.

What is claimed is:

1. A hybrid cooling system that cools an electronic device, the electronic device including a heat-generating component, the hybrid cooling system comprising:
a container that contains a dielectric immersion cooling liquid, the electronic device being, at least in part, immersed in the dielectric immersion cooling liquid;
a liquid cooling block through which a channelized cooling liquid is conveyed, the liquid cooling block in thermal contact with the heat-generating component, the channelized cooling liquid having a density that is higher than a density of the dielectric immersion cooling liquid; and
a testing arrangement disposed in a bottom portion of the container to determine a presence of the channelized cooling liquid in the bottom portion of the container that indicates a leak of the channelized cooling liquid into the dielectric immersion cooling liquid.

2. The hybrid cooling system according to claim 1, wherein the container comprises an immersion case containing the electronic device.

3. The hybrid cooling system according to claim 1, wherein the dielectric immersion cooling liquid flows over the electronic device, and wherein the container comprises a collection tray (508) disposed below the electronic device that collects liquid flowing off of the electronic device.

4. The hybrid cooling system according to claim 1, wherein the testing arrangement comprises a float arrangement incorporating a floating element and a detector that determines when the floating element has reached a predetermined height above a bottom of the container to indicate a leak; and
wherein the floating element has a density that is higher than the density of the dielectric immersion cooling liquid and lower than a density of the channelized cooling liquid, such that the floating element is configured to sink in the dielectric immersion cooling liquid and to float on top of the channelized cooling liquid.

5. The hybrid cooling system according to claim 4, wherein the float arrangement further comprises a constraining mechanism that constrains motion of the floating element.

6. The hybrid cooling system according to claim 1, wherein the channelized cooling liquid has a greater conductivity than the dielectric immersion cooling liquid, and wherein the testing arrangement comprises a conductivity sensor.

7. The hybrid cooling system according to claim 1, wherein the channelized cooling liquid has a pH that is different from a pH of the dielectric immersion cooling liquid, and wherein the testing arrangement comprises a pH sensor.

8. The hybrid cooling system according to claim 1, wherein the testing arrangement comprises a resealable closure configured to provide access to a sample of liquid from the bottom portion of the container.

9. The hybrid cooling system according to claim 8, wherein the resealable closure comprises a valve.

10. The hybrid cooling system according to claim 1, wherein the testing arrangement is mounted in the container through a standardized opening in the bottom portion of the container, the standardized opening configured to receive any one of a variety of testing arrangements.

11. The hybrid cooling system according to claim 1, wherein:
the channelized cooling liquid is conductive;
the testing arrangement comprises circuitry including a first conducting strip and a second conducting strip that are separated by a non-conducting region of the circuitry; and
a circuit formed by the first conducting strip and the second conducting strip is closed when at least a portion of the first conducting strip and at least a portion of the second conducting strip are submerged in the channelized cooling liquid.

12. The hybrid cooling system according to claim 11, wherein the circuitry comprises flexible circuitry attached to a surface of the bottom portion of the container using an adhesive.

13. The hybrid cooling system according to claim 11, wherein the circuitry comprises a printed circuit board.

14. The hybrid cooling system according to claim 1, wherein a bottom surface of the container is sloped.

15. A hybrid cooling system that cools an electronic device, the electronic device including a heat-generating component, the hybrid cooling system comprising:
a container adapted and configured to receive a dielectric immersion cooling liquid so that the electronic device is, at least in part, immersed in the dielectric immersion cooling liquid when the dielectric immersion liquid is present in the container;
a liquid cooling block adapted and configured to circulate a channelized cooling liquid, the liquid cooling block in thermal contact with the heat-generating component, the channelized cooling liquid having a density that is higher than a density of the dielectric immersion cooling liquid; and
a testing arrangement disposed in a bottom portion of the container to determine a presence of the channelized cooling liquid in the bottom portion of the container that indicates a leak of the channelized cooling liquid into the dielectric immersion cooling liquid.
